(19) United States
(12) Patent Application Publication
(10) Pub. No.: US 2009/0066320 A1
(43) Pub. Date: Mar. 12, 2009

(54) DEADBOLT SENSOR FOR SECURITY SYSTEMS

(75) Inventor: David T. Posey, Blanchard, OK (US)

Correspondence Address: MCAFEE & TAFT;TENTH FLOOR, TWO LEADERSHIP SQUARE, 211 NORTH ROBINSON, OKLAHOMA CITY, OK, 73102, US

(73) Assignee: HERMETIC SWITCH, INC., Chickasha, OK (US)

(21) Appl. No.: 11/883,282

(22) PCT Filed: Jan. 28, 2005
(86) PCT No.: PCT/US2005/003473

§ 371 Date: Oct. 20, 2008

(51) Int. Cl. G01R 33/00

(52) U.S. Cl. 324/207.13; 324/207.11

(57) ABSTRACT

The current invention provides an improved security system sensor assembly. The sensor assembly of the current invention reduces installation costs when adding a security system. to an existing structure by eliminating the need to install magnets on existing doors. The sensor assembly of the current invention allows the security system to monitor the locked or unlocked status of each monitored door by sensing when a deadbolt lock is in the locked position. Additionally, the sensor assembly will alert the security system when a deadbolt lock is moved from the locked position without authorization.

### BACKGROUND OF THE INVENTION

The current invention provides improvements to commercial and residential security systems. A typical security system requires the installation of a sensor in the door frame and a magnet in the door. When armed, the security system triggers a predetermined response when the sensor detects movement of the door away from the frame. Unfortunately, such security systems do not indicate the locked/unlocked status of the monitored door. Rather, the security system merely indicates whether or not the door is closed. Thus, premises guarded by the security system may not be adequately secured by locked doors.

A single unlocked door may provide a sufficient breach in security for intruders to steal or destroy a building's contents before police or guards can respond to the alert signaled by the door movement sensor. Thus, it would be desirable to provide a security system which readily indicates the status of each monitored door. It would also be desirable for the security system to signal an alarm when the lock on the door is “jimmied” or otherwise moved without proper authorization.

The current invention provides an improved security system utilizing common deadbolt locks. The improved security system monitors the status of the locks indicating whether or not the doors are closed and locked. Additionally, the current invention simplifies security system installation in currently existing structures. The current invention is particularly suited for installation in conjunction with pre-existing deadbolt locks commonly found in residential and business structures.

### SUMMARY OF THE INVENTION

The current invention provides an improved security system. The security system is suitable for retrofitting existing structures and for new construction. In one embodiment, the current invention comprises a sensor assembly suitable for use with a common deadbolt lock mechanism. The sensor assembly indicates the locked or unlocked status of the door by sensing the position of the deadbolt within the sensor assembly. The sensor assembly is positioned behind a conventional strike plate and defines a cavity for receiving the deadbolt. The assembly also includes a sensor for detecting the door's locked and unlocked status. The sensor is carried at the terminal end of the deadbolt cavity or positioned within a sensor cavity portion of the sensor assembly. In a preferred embodiment the sensor is a reed switch capable of detecting changes in a magnetic flux field.

In another embodiment, the current invention provides a sensor assembly suitable for use with previously installed deadbolt locks. The sensor assembly is suitable for installation behind a conventional strike plate. The sensor assembly comprises a deadbolt cavity and a steel sensing sensor. The sensor is laterally adjustable within the assembly thereby permitting fine tuning of the security system. The steel sensing sensor may be a magnetic flux sensor. The sensor may be carried by the sensor assembly or housed within a sensor cavity. Preferably, the sensor incorporates a reed switch which opens and closes in response to changes in a magnetic flux field. More preferably, the reed switch senses deadbolt movement away from the sensor prior to the deadbolt moving to an unlocked position.

The current invention further provides a method for controlling and activating security systems. The method of the current invention utilizes a doorway having a doorframe and door positioned therein. When closed, the door is locked by means of a conventional deadbolt lock mechanism. The method comprises removing the strike plate associated with the deadbolt lock and positioning a sensor assembly in the doorframe. Subsequently the strike plate is reinstalled thereby securing the sensor in the doorframe. The sensor assembly includes a steel sensing sensor and a deadbolt cavity for receiving the deadbolt of the deadbolt lock mechanism. The sensor assembly is connected to the security system. When the security system is activated the sensor signals the door's locked or unlocked status to the security system. Any unauthorized movement of the deadbolt will be detected by the sensor which will trigger the appropriate action by the security system.

### BRIEF DESCRIPTION OF THE DRAWINGS

FIG. 1 depicts a strike plate.

FIG. 2 depicts a side cut-away view of the sensor assembly housing.

FIG. 3 depicts an alternate embodiment of the sensor assembly.

FIG. 4 depicts a front view of the sensor assembly including optional flanges.

FIG. 5 depicts a side view of the sensor.

FIG. 6 depicts a security system utilizing the sensor assembly with a deadbolt lock in a door.

### DETAILED DESCRIPTION OF THE PREFERRED EMBODIMENTS OF THE INVENTION

The current invention provides improvements to home and business security systems. Common security system elements such as control panels, hard wiring connections and wireless communication devices are well known to those skilled in the art and will not be discussed herein. Rather, the following disclosure will focus on the novel aspects of the various embodiments of the current invention.

The current invention is equally useful when installing security systems in new structures, for retrofitting existing security systems and when installing security systems in existing structures. The current invention takes advantage of the steel typically used in a conventional deadbolt lock. Ferrous materials such as steel are known to disrupt the lines of magnet flux which characterize a magnetic field. Reed switches, such as the type disclosed in U.S. Pat. Nos. 5,293,523 and 5,128,641, incorporated herein by reference, respond to changes in a magnetic field. The reed switch may normally be an opened or a closed switch when the magnetic field is undisturbed. When the magnet flux field is disturbed or altered by a magnetizable or magnetically permeable substance the switch will move to the other position. Thus, switch actuation occurs when the magnet flux field is altered by the presence or absence of an object such as a deadbolt.

As used herein, a conventional deadbolt lock has a sufficient concentration of steel, iron or other magnetically permeable substance such that the proximity thereof will disrupt or alter a magnet flux field generated by a reed switch. Thus, when positioned proximate to a reed switch, a conventional deadbolt will switch the reed switch between its open and closed positions. Conventional deadbolt locks do not require modification in order to activate a reed switch suitable for use in the current invention.

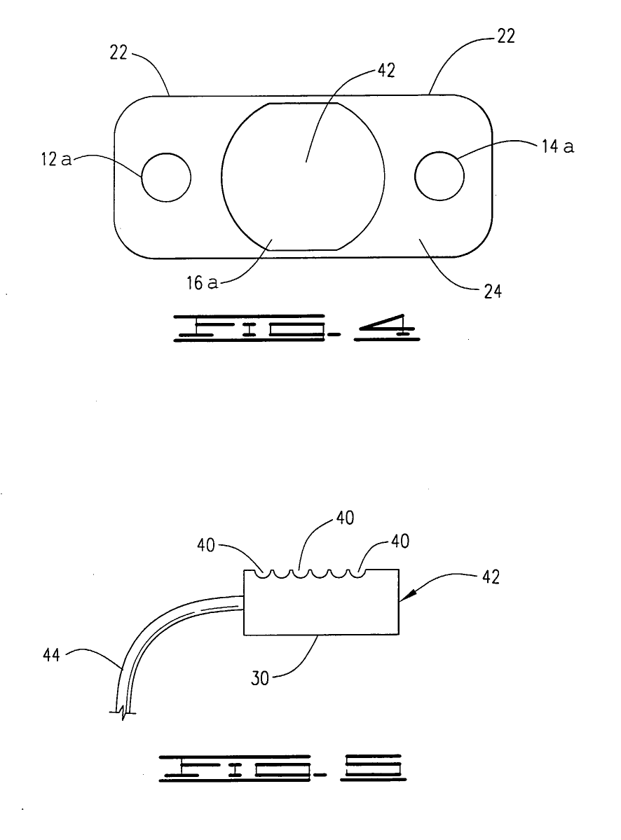

With reference now to the drawings, the current invention provides a sensor assembly 10. Sensor assembly 10 is secured within a door frame 46 by a conventional strike plate 11 using screws (not shown) through holes 12 and 14 or other conventional means. A central hole 16 is provided in strike plate 11 for receiving a deadbolt 18 of a conventional deadbolt lock mechanism 20. Sensor assembly 10 comprises a housing 24 defining a deadbolt cavity 26 for receiving deadbolt 18. Additionally, sensor assembly 10 provides a sensor 30 at a terminal end 27 of deadbolt cavity 26. Sensor 30 is preferably positioned within a sensor cavity 28. In the preferred embodiment sensor 30 is laterally adjustable within sensor cavity 28. In an alternative embodiment shown in FIG. 3, sensor 30 is incorporated as a fixed component on housing 24 at the terminal end 27 of deadbolt cavity 26. Laterally adjusting sensor 30 enhances security system sensitivity and accommodates differences in deadbolt 18 length and any gaps between door 48 and door frame 46.

In one preferred embodiment, lateral positioning of sensor 30 is maintained by cooperation of one or two pins 36, located within holes 38 found in housing 24, and scallops 40 carried by sensor 30. Following determination of the optimum operation depth of deadbolt 18, sensor 30 is positioned within sensor cavity 28 and secured by engagement of pins 36 with scallops 40. Optionally, pins 36 are sufficiently flexible to permit lateral slippage of sensor 30 when sufficient pressure is applied to sensor end 42 of sensor 30. More precisely, when pressure is applied to sensor 30, pin(s) 36 flex upwards allowing sensor 30 to move laterally until pin(s) 36 align with the next scallop 40. Thus, optimum positioning of sensor 30 within sensor cavity 28 can be achieved by turning deadbolt 18 to the locked position. While FIG. 6 depicts scallops 40 engaging pins 36, other engagement elements such as ridges, grooves or even Velcro® are contemplated by the current invention.

Depending on the security system, sensor 30 is hardwired to the security system and power source by wire leads 44. Alternatively, sensor 30 may be incorporated into a wireless unit (not shown) having its own source of power (not shown). The actual connection of sensor 30 to the security system is not considered to be a part of the current invention and may be accomplished by conventional methods known to those skilled in the art.

With continued reference to the drawings, the installation and operation of the current invention will be described. Sensor assembly 10 can be manufactured in sizes to accommodate common industry standards. Thus, sensor assembly 10 requires minimal or no modification to a conventional door frame 46. In general, the original strike plate 11 is removed and sensor assembly 10 positioned behind and/or secured to original strike plate 11. For example, in one embodiment depicted by FIG. 4, housing 24 includes optional flanges 22 corresponding to strike plate 11 including corresponding holes 12a, 14a and 16a. In this embodiment, sensor assembly 10 is retained in position by flanges 22 sandwiched between strike plate 11 and door frame 46. Other embodiments may use flanges 22 having lengths less than the distance to holes 12 and 14 or may omit the flanges. Since housing 24 typically has outside dimensions greater than hole 16 found in strike plate 11, flanges 22 may be omitted and housing 24 secured within door frame 46 solely by strike plate 11 as depicted in FIG. 6. If necessary, door frame 46 may be drilled-out to accommodate the length of sensor assembly 10.

Preferably sensor 30 is positioned within sensor cavity 28 prior to installing sensor assembly 10. Normally, sensor 30 will be positioned within sensor cavity 28 by positioning housing 24 over deadbolt 18 with deadbolt 18 in the locked position. Once positioned, sensor 30 is secured by one or two pins 36 passing through hole(s) 38 and engaging scallop 40. Alternatively, when using flexible pins 36, sensor 30 may be positioned within sensor cavity 28 and extending into deadbolt cavity 26 prior to installing sensor assembly 10 within door frame 46. Following installation, deadbolt 18 is moved to the locked position forcing sensor 30 laterally through sensor cavity 28 until it is secured at the desired location by pin(s) 36.

Either positioning method is suitable for optimizing the location of sensor 30 within sensor cavity 28 to the length of deadbolt 18. Preferably, sensor end 42 will be immediately adjacent to deadbolt 18 when deadbolt mechanism 20 is in the locked position. In general, deadbolt 18 should be within about 1.5 mm to about 9 mm from sensor end 42 when in the locked position. More preferably, deadbolt 18 should be within about 1.5 mm to about 6 mm from sensor end 42.

As noted above, the current invention contemplates alternate embodiments for securing sensor 30 as part of sensor assembly 10. As noted above, one preferred embodiment positions sensor 30 within sensor cavity 28. However, in another embodiment, sensor 30 is fixedly secured to housing 24. In this embodiment, deadbolt cavity 26 preferably has a length corresponding to the length of deadbolt 18 in the locked position. Sensor 30 may then be secured directly to housing 24 at end 27 of deadbolt cavity 26 without further adjustment. This embodiment may require trimming of housing 24 prior to securing sensor 30 thereto.

Following positioning of sensor 30 at the desired location, sensor assembly 10 is ready for use with the security system. Since sensor 30 is capable of detecting the presence of deadbolt 18 without further modification, the current invention eliminates the step of installing a separate magnet (not shown) in door 48 or on deadbolt 18. Thus, conventional deadbolt 18 provides a suitable trigger for activating sensor 30. Clearly, sensor assembly 10 will reduce the costs of installing security systems in new and existing structures.

Once sensor assembly 10 has been installed and linked to the security system, the security system will indicate each monitored door's locked or unlocked status. With the system activated and deadbolt 18 in the locked position, sensor 30 will signal the presence of deadbolt 18 within deadbolt cavity 26. If deadbolt 18 is moved away from sensor end 42 without appropriate authorization, then sensor 30 will trigger an alarm or will otherwise activate the security system.

By use of steel sensing sensor 30, for example, a reed switch as disclosed in U.S. Pat. Nos. 5,293,523 and 5,128,641, the current invention provides improved security when compared to prior art security systems. Prior art security systems typically do not recognize an unauthorized entry until door 48 opens. In contrast, the current invention provides the ability to detect “picking” or “jimmying” of deadbolt lock mechanism 20. In the preferred embodiment, once the security system has been engaged and the doors locked, sensor 30 will activate the security system during movement of deadbolt 18 away from sensor end 42. Preferably, sensor 30 will activate the security system once deadbolt 18 has moved about 10 mm to about 15 mm from sensor end 42. In general, sensor 30 will activate the security system prior deadbolt 18 retracting less than 50% out of deadbolt cavity 26. More preferably, retracting less than about 6% of the length of deadbolt 18 from within deadbolt cavity 26 will activate the security system. For example, if deadbolt 18 penetrates 2.5 cm into deadbolt cavity 26, then sensor 30 will activate the security system when deadbolt 18 has been retracted only about 15 mm or less from sensor end 42.

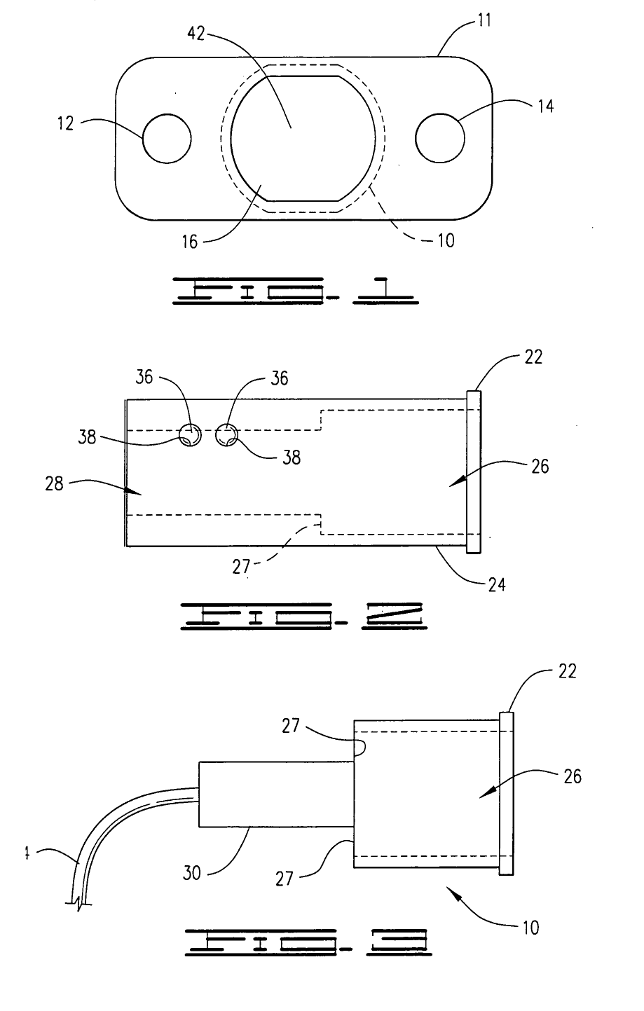

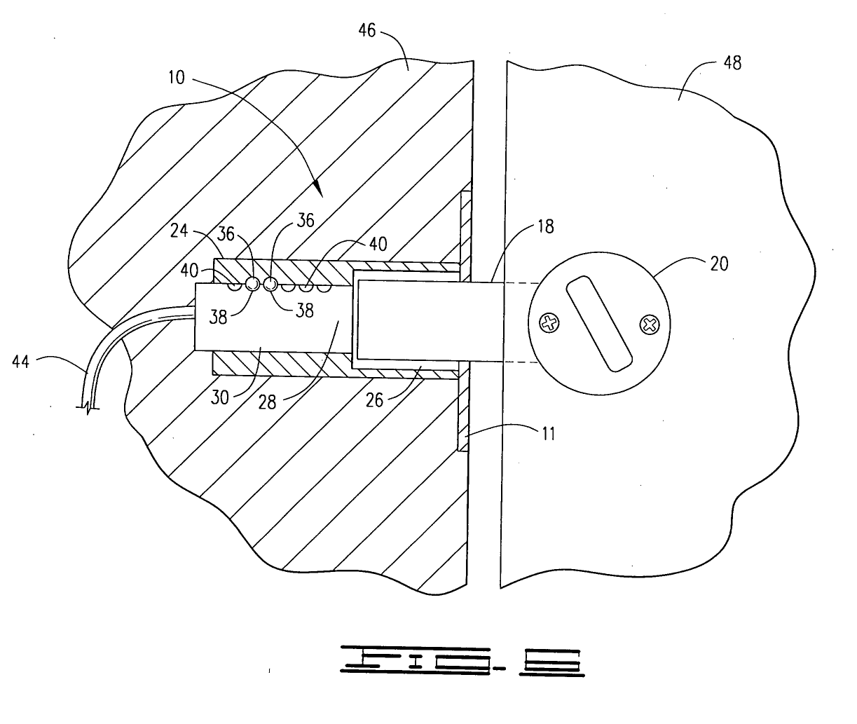

While the present invention has been described in detail with reference to FIGS. 1-6, other embodiments will be apparent to those skilled in the art. For example, FIGS. 1-6 depict a conventional deadbolt lock turned by a key or knob. However, the current invention would also operate with a slide bolt or the similar steel based “deadbolt” locking mechanism. Accordingly, the foregoing specification is considered exemplary with the true scope and spirit of the invention being indicated by the following claims.

1. A sensor assembly suitable for incorporation with a security system, said sensor assembly comprising:
a housing, said housing defining a deadbolt cavity for receiving a conventional deadbolt; and,
a sensor carried on or within said housing, said sensor determines the presence of a conventional deadbolt within said deadbolt cavity.

2. The sensor assembly of claim 1, wherein said sensor assembly further comprises a sensor cavity suitable for housing said sensor.

3. The sensor assembly of claim 2, wherein said sensor is laterally adjustable within said sensor cavity.

4. The sensor assembly of claim 3, wherein said sensor is retained within said sensor cavity by at least one pin.

5. The sensor assembly of claim 4, wherein said pin engages one of a plurality of scallops carried by said sensor and said pin is sufficiently flexible to permit movement of said sensor laterally when engaged by said deadbolt.

6. The sensor assembly of claim 3, wherein said sensor is positioned within said sensor cavity such that the distance between said sensor and a deadbolt positioned in a locked position within said deadbolt cavity is immediately adjacent to about 9 mm.

7. The sensor assembly of claim 3, wherein said sensor is positioned within said sensor cavity such that the distance between said sensor and a deadbolt positioned in a locked position within said deadbolt cavity is immediately adjacent to about 6 mm or less.

8. The sensor assembly of claim 1, wherein said sensor detects changes in a magnetic flux field.

9. The sensor assembly of claim 1, wherein said sensor is a hermetically sealed magnetic reed switch.

10. The sensor assembly of claim 3, wherein said sensor signals said security system when said deadbolt is moved away from said sensor.

11. The sensor assembly of claim 3, where said sensor signals said security system when said deadbolt has moved about 10 mm to about 15 mm away from said sensor.

12. A sensor assembly suitable for incorporation with a security system and determining the locked or unlocked status of a conventional deadbolt lock, said sensor assembly comprising:
a housing, said housing defining a deadbolt cavity for receiving a conventional deadbolt and further defining a sensor cavity; and,
a sensor, positioned within said sensor cavity, said sensor being laterally adjustable within said sensor cavity, said sensor determines the presence of a conventional deadbolt within said deadbolt cavity when said deadbolt is located immediately adjacent to said sensor to about 9 mm from said sensor.

13. The sensor assembly of claim 12, wherein said sensor is retained within said sensor cavity by at least one pin.

14. The sensor assembly of claim 13, wherein said pin engages one of a plurality of scallops carried by said sensor and said pin is sufficiently flexible to permit movement of said sensor laterally when engaged by said deadbolt.

15. The sensor assembly of claim 12, wherein said sensor is positioned within said sensor cavity such that the distance between said sensor and a deadbolt positioned in a locked position within said deadbolt cavity is immediately adjacent to about 9 mm or less.

16. The sensor assembly of claim 12, wherein said sensor is positioned within said sensor cavity such that the distance between said sensor and a deadbolt positioned in a locked position within said deadbolt cavity is immediately adjacent to about 6 mm or less.

17. The sensor assembly of claim 12, wherein said sensor detects changes in a magnetic flux field.

18. The sensor assembly of claim 12, wherein said sensor is a hermetically sealed magnetic reed switch.

19. The sensor assembly of claim 12, wherein said sensor signals said security system when said deadbolt is moved away from said sensor.

20. The sensor assembly of claim 12, where said sensor signals said security system when said deadbolt has moved about 10 mm to about 15 mm away from said sensor.

21. A sensor assembly suitable for incorporation with a security system and determining the locked or unlocked status of a conventional deadbolt lock, said sensor assembly comprising:
a housing, said housing defining a deadbolt cavity for receiving said deadbolt and further defining a sensor cavity; and,
a sensor laterally adjustable within said sensor cavity, said sensor determines the presence of said conventional deadbolt within said deadbolt cavity, said sensor being secured within said sensor cavity such that said deadbolt is immediately adjacent to said sensor to within about 9 mm of said sensor when said deadbolt is in the locked position and wherein said sensor signals movement of said deadbolt from the locked to the unlocked position to said security system when said deadbolt has moved about 10 mm to about 15 mm away from said sensor.

22. The sensor assembly of claim 21, wherein said sensor is retained within said sensor cavity by at least one pin.

23. The sensor assembly of claim 22, wherein said pin engages one of a plurality of scallops carried by said sensor and said pin is sufficiently flexible to permit movement of said sensor laterally when engaged by said deadbolt.

24. The sensor assembly of claim 21, wherein said sensor detects changes in a magnetic flux field.

25. The sensor assembly of claim 21, wherein said sensor is a hermetically sealed magnetic reed switch.

26. The sensor assembly of claim 21, wherein said sensor is positioned within said sensor cavity such that the distance between said sensor and a deadbolt positioned in a locked position within said deadbolt cavity is immediately adjacent to about 6 mm or less.

27. A sensor assembly suitable for incorporation with a security system and determining the locked or unlocked status of a conventional deadbolt lock, said sensor assembly comprising:
a housing, said housing defining a deadbolt cavity for receiving said conventional deadbolt and further defining a sensor cavity; and,
a sensor laterally adjustable within said sensor cavity, said sensor being a hermitically sealed magnetic reed switch capable of determining the presence of said conventional deadbolt within said deadbolt cavity, said sensor being secured within said sensor cavity such that said sensor is immediately to adjacent to said deadbolt to within about 6 mm of said deadbolt when said deadbolt is in the locked position and wherein said sensor signals movement of said deadbolt from the locked to the unlocked position to said security system when said deadbolt has moved about 10 mm to about 15 mm away from said sensor.

28. A method for controlling a security system comprising the steps of:
providing a doorway having a doorframe wherein a door positioned in said doorway carries a conventional deadbolt and said doorframe carries a strike plate engaged by said deadbolt when said deadbolt is in the locked position;
removing the strike plate from said doorframe and positioning a sensor assembly in said doorframe, said sensor assembly includes a deadbolt cavity and a steel sensing sensor; and,
connecting said sensor to said security system:
using said sensor to indicate the locked status of said deadbolt and to control activation of said security system in response to unauthorized movement of said deadbolt.

29. The method of claim 28, wherein said sensor assembly includes a sensor cavity and wherein said steel sensing sensor is laterally adjustable within said sensor cavity and further comprising the step of adjusting the position of said sensor within said sensor cavity following installation of said sensor assembly in said doorframe by closing said door and moving said deadbolt to the locked position.

30. The method of claim 28, wherein said sensor assembly includes a sensor cavity and said steel sensing sensor is laterally adjustable within said sensor cavity and further comprising the step of adjusting the position of said sensor within said sensor cavity prior to installation of said sensor assembly in said door frame by positioning said sensor assembly over said deadbolt lock when said deadbolt lock is in the locked position and securing said sensor within said sensor cavity.

31. The method of claim 29, wherein said sensor is secured within said sensor cavity such that when said deadbolt lock is in the locked position said deadbolt is immediately adjacent to about 6 mm from said sensor.

32. The method of claim 30, wherein said sensor is secured within said sensor cavity such that when said deadbolt lock is in the locked position said deadbolt is immediately adjacent to about 6 mm from said sensor.

33. The method of claim 28, wherein said sensor is a hermetically sealed magnetic reed switch.

34. The method of claim 28, further comprising the step of said sensor activating said security system when said deadbolt moves further than about 10 mm to about 15 mm away from said sensor.

35. A method for controlling a security system comprising the steps of:
providing a doorway having a door frame wherein a door positioned in said doorway carries a conventional deadbolt lock mechanism including a conventional deadbolt and said doorframe carries a strike plate engaged by said deadbolt when said deadbolt is in the locked position;
positioning a sensor assembly in said doorframe behind said strike plate, said sensor assembly includes a deadbolt cavity, a sensor cavity and a sensor positioned within said sensor cavity, said sensor capable of detecting changes in a magnetic flux field;
connecting said sensor to said security system; and, using said sensor to determine the locked status of said conventional deadbolt and to control the activation of said security system in response to unauthorized movement of said conventional deadbolt.

36. The method of claim 35, wherein said sensor is a hermetically sealed magnetic reed switch.

37. The method of claim 35, wherein said sensor is secured within said sensor cavity such that when said deadbolt lock is in the locked position said sensor is immediately adjacent to said deadbolt to about 6 mm from said deadbolt.

38. The method of claim 35, wherein said sensor partially extends into said deadbolt cavity and further comprising the step of adjusting the position of said sensor within said sensor cavity following installation of said assembly in said doorframe by closing said door and moving said deadbolt to the locked position.

39. The method of claim 38, wherein said sensor is secured within said sensor cavity such that when said deadbolt is in the locked position said sensor is immediately adjacent to said deadbolt to about 6 mm from said deadbolt.

40. The method of claim 35, wherein said sensor partially extends into said deadbolt cavity and further comprising the step of adjusting the position of said sensor within said sensor cavity prior to installation of said sensor assembly in said door frame by positioning said sensor assembly over said deadbolt when said deadbolt is in the locked position and securing said sensor within said sensor cavity.

41. The method of claim 40, wherein said sensor is secured within said sensor cavity such that when said deadbolt is in the locked position said sensor is immediately adjacent to said deadbolt about 6 mm from said deadbolt.

42. The method of claim 35, further comprising the step of said sensor activating said security system when said deadbolt moves further than about 10 mm to about 15 mm away from said sensor.
